(19) United States
(12) Patent Application Publication
(10) Pub. No.: US 2023/0132801 A1
(43) Pub. Date: May 4, 2023

(54) THIN FILM LOUDSPEAKER AND ELECTRONIC DEVICE WITH LOUDSPEAKER

(71) Applicants: Interface Technology (ChengDu) Co., Ltd., Chengdu (CN); INTERFACE OPTOELECTRONICS (SHENZHEN) CO., LTD., Shenzhen (CN); INTERFACE OPTOELECTRONICS (WUXI) CO., LTD., Wuxi (CN); GENERAL INTERFACE SOLUTION LIMITED, Zhunan (TW)

(72) Inventors: MING-KUEI CHI, New Taipei (TW); SHIH-CHIEH HUANG, Hsinchu (TW)

(21) Appl. No.: 17/562,307

(22) Filed: Dec. 27, 2021

(30) Foreign Application Priority Data
Oct. 28, 2021 (CN) 202111263561.7

(51) Int. Cl. H04R 17/00; H01L 41/193

(52) U.S. Cl. CPC H04R 17/00; H01L 41/193

(57) ABSTRACT

A loudspeaker includes a first electrode layer, a second electrode layer arranged opposite to the first electrode layer, a piezoelectric layer between the first electrode layer and the second electrode layer. The first electrode layer is configured for receiving a first driving voltage. The second electrode layer is configured for receiving a second driving voltage. The piezoelectric layer having an outer contour that is smooth. The piezoelectric layer is configured for making sound by generating mechanical vibration according to the first driving voltage and the second driving voltage.

The present application is based on, and claims priority from, China application number 202111263561.7, filed Oct. 28, 2021, the disclosure of which is hereby incorporated by reference herein in its entirety.

### FIELD

The subject matter herein generally relates to a loudspeaker and an electronic device having the loudspeaker.

### BACKGROUND

Electronic devices having sound playback function, such as mobile phones, computers, televisions, etc., need to be equipped with loudspeakers to realize the sound playback function. Traditional loudspeakers produce sound by mechanical vibration. A traditional loudspeaker includes many electronic components to realize mechanical vibration, resulting in a large overall volume. For small electronic devices (such as mobile phones) having traditional loudspeakers leaves little internal space for other components. Further, a traditional loudspeaker is limited by achievable vibration frequency and the sound volume is not high. Holes in a shell of the electronic device are usually required to facilitate a propagation of sound.

Thin film loudspeakers are widely used in various electronic devices due to their small size, however. sound generation by thin film loudspeakers is not optimal. Therefore, there is room for improvement in the art.

### BRIEF DESCRIPTION OF THE DRAWINGS

Implementations of the present technology will now be described, by way of embodiments only, with reference to the attached figures.

FIG. 1 is an isometric view of an electronic device according to a first embodiment of the present disclosure.

FIG. 2 is a cross-sectional view of the electronic device in FIG. 1 along line II-II.

FIG. 3 is an isometric view of a loudspeaker of the electronic device in FIG. 1.

FIG. 4 is a bottom view of a screen of the electronic device in FIG. 1 and a piezoelectric layer of the loudspeaker in FIG. 2.

FIG. 5 is a variation curve of a volume of the loudspeaker in FIG. 2 with the vibration frequency of the piezoelectric layer.

FIG. 6 is a bottom view of a screen and a piezoelectric layer of the electronic device according to a second embodiment of the present disclosure.

FIG. 7 is a variation curve of a volume of the loudspeaker with the vibration frequency of the piezoelectric layer in the second embodiment.

FIG. 8 is a bottom view of a screen and a piezoelectric layer of the electronic device according to a third embodiment of the present disclosure.

FIG. 9 is a variation curve of a volume of the loudspeaker with the vibration frequency of the piezoelectric layer in the third embodiment.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “coupled” is defined as coupled, whether directly or indirectly through intervening components, and is not necessarily limited to physical connections. The connection can be such that the objects are permanently coupled or releasably coupled. The term “comprising” when utilized, means “including, but not necessarily limited to”; it specifically indicates open-ended inclusion or membership in the so-described combination, group, series, and the like.

### First Embodiment

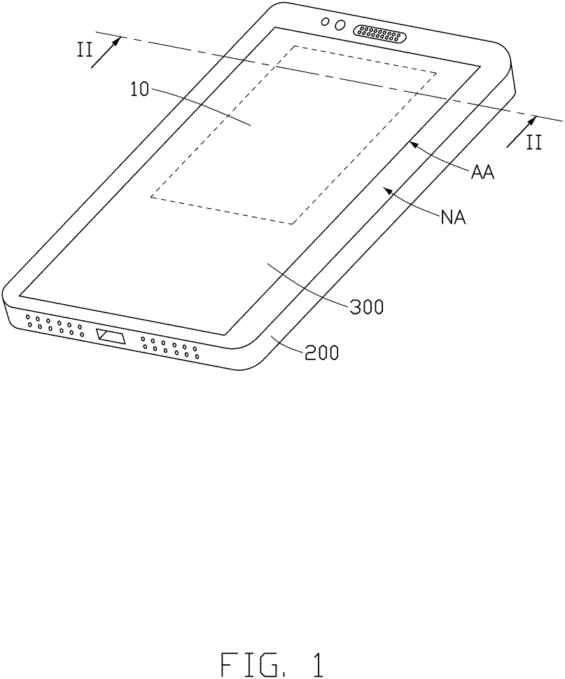

Referring to FIG. 1, an electronic device 100 includes a loudspeaker 10 to realize a sound playback function. The electronic device 100 may be a device with a sound playback function such as a mobile phone, a computer, a television, a radio, etc. In this embodiment, the electronic device 100 is a mobile phone.

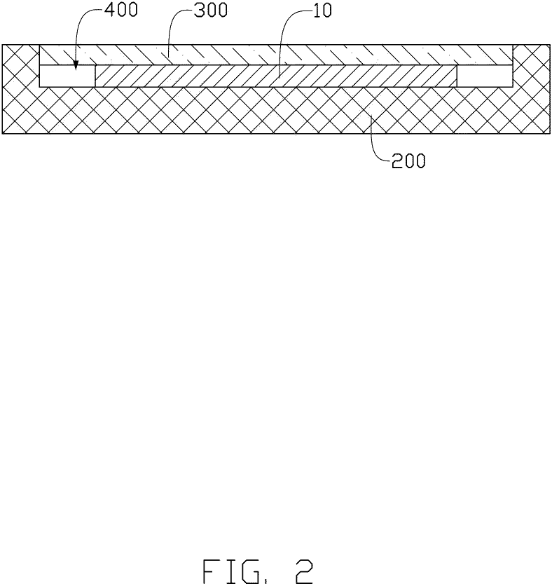

The electronic device 100 defines a display area AA and a non-display area NA surrounding and connected to the display area AA. The display area AA is an area where an image can be displayed, the non-display area NA cannot display images. The electronic device 100 includes a housing 200 and a screen 300. As shown in FIG. 2, the housing 200 and the screen 300 cooperate to form a closed receiving space 400, and the loudspeaker 10 is located in the closed receiving space 400. The screen 300 is partially located in the display area AA and the speaker 10 is at least partially located in the display area AA. That is, in the present embodiment, the loudspeaker 10 is arranged under the screen.

In this embodiment, the loudspeaker 10 is a thin film loudspeaker. The loudspeaker 10 includes piezoelectric material, and the loudspeaker 10 makes sound by mechanical vibration generated by the piezoelectric material under the action of an electric field.

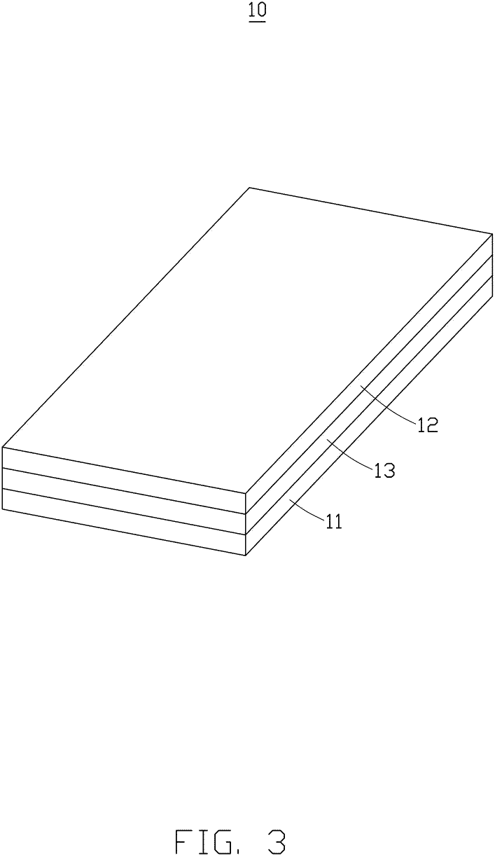

As shown in FIG. 3, in this embodiment, the loudspeaker 10 includes a first electrode layer 11, a second electrode layer 12, and a piezoelectric layer 13 between the first electrode layer 11 and the second electrode layer 12. The first electrode layer 11 and the second electrode layer 12 are arranged opposite to each other. The piezoelectric layer 13 is located in an area the first electrode layer 11 directly opposite to the second electrode layer 12. The first electrode layer 11 and the second electrode layer 12 are made of conductive material, such as metal. The piezoelectric layer 13 is a thin film formed of piezoelectric material. In this embodiment, the piezoelectric layer 13 is formed of a flexible piezoelectric material, such as polyvinylidene fluoride (PVDF). In this embodiment, the piezoelectric layer 13 is composed of flexible PVDF, allowing the piezoelectric layer 13 to be cut into various shapes and durable.

The first electrode layer 11 is used to receive a first driving voltage, and the second electrode layer 12 is used to receive a second driving voltage. When the first driving voltage and the second driving voltage are different, a voltage difference is formed between the first electrode layer 11 and the second electrode layer 12, and an electric field is formed between the first electrode layer 11 and the second electrode layer 12. The piezoelectric layer 13 generates mechanical vibration under the electric field and moves the surrounding air to realize sound generation.

In this embodiment, both the first electrode layer 11 and the second electrode layer 12 are continuous as conductive structures. That is, the first electrode layer 11 and the second electrode layer 12 have no etching or patterns and no hollow areas.

Referring to FIG. 1 to FIG. 3, in this embodiment, shapes of the first electrode layer 11, the second electrode layer 12 and the piezoelectric layer 13 are the same. That is, the projections of the first electrode layer 11, the second electrode layer 12 and the piezoelectric layer 13 on the screen 300 completely coincide.

In at least one embodiment, projections of the first electrode layer 11 and the second electrode layer 12 on the screen 300 completely coincide, and the projection of the first electrode layer 11 and the projection of the second electrode layer 12 on the screen 300 is greater than the projection of the piezoelectric layer 13 on the screen 300. That is, the projection of the piezoelectric layer 13 on the screen 300 is completely overlapped by the projection of the first electrode layer 11 and the projection of the second electrode layer 12 on the screen 300, and the projection area of the piezoelectric layer 13 on the screen 300 is less than the projection area of the first electrode layer 11 and the projection area of the second electrode layer 12 on the screen 300. Near the edges of the first electrode layer 11 and the second electrode layer 12, the electric field may be weak. In at least one embodiment, by setting the projection of the first electrode layer 11 and the projection of the second electrode layer 12 on the screen 300 to completely overlap the projection of the piezoelectric layer 13 on the screen 300, problems of performance of the piezoelectric layer 13 in a weak field are avoided.

The electronic device 100 also includes a flexible circuit board (not shown) electrically connected to both the first electrode layer 11 and the second electrode layer 12 to apply the first driving voltage to the first electrode layer 11 and the second driving voltage to the second electrode layer 12.

By changing a voltage difference between the first electrode layer 11 and the second electrode layer 12, the vibration frequency of the piezoelectric layer 13 can be changed, and the volume of the loudspeaker 10 can also be changed.

In this embodiment, the first driving voltage on the first electrode layer 11 keeps constant, and the voltage difference between the first electrode layer 11 and the second electrode layer 12 is changed by changing the second driving voltage on the second electrode layer 12.

In at least one embodiment, the second driving voltage on the second electrode layer 12 may keep constant, and the voltage difference between the first electrode layer 11 and the second electrode layer 12 may be changed by changing the first driving voltage on the first electrode layer 11. Alternatively in at least one embodiment, both the first driving voltage and the second driving voltage may be changed to change the voltage difference between the first electrode layer 11 and the second electrode layer 12.

In this embodiment, according to different shapes, sizes, materials, etc. of the piezoelectric layer 13, the vibration frequency of the piezoelectric layer 13 can be different under the driving of the same voltage difference, resulting in different volume of the loudspeaker 10. In this embodiment, the piezoelectric layer 13 is parallel to the screen 300, and the shape of the piezoelectric layer 13 refers to the shape of the projection of the piezoelectric layer 13 on the screen 300.

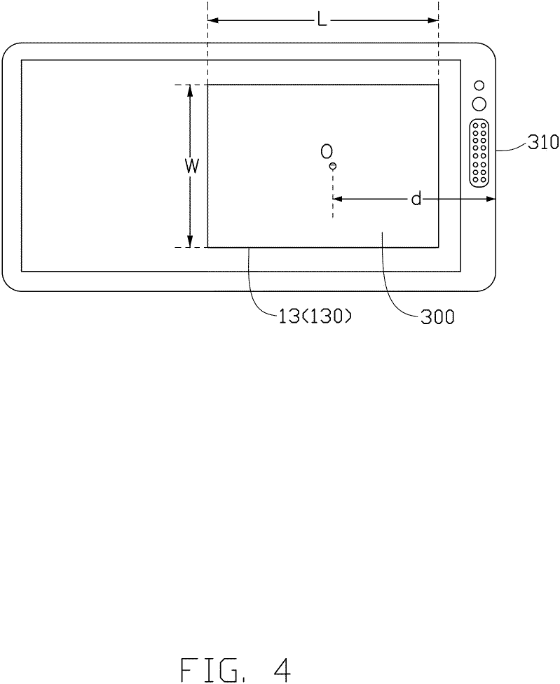

As shown in FIG. 4, in this embodiment, the shape of the piezoelectric layer 13 is rectangular. That is, the projection 130 of the piezoelectric layer 13 on the screen 300 is rectangular in shape. The long side of the piezoelectric layer 13 is defined as L and the short side is defined as W. In this embodiment, the electronic device 100 has a handset (not shown), and the edge 310 of the screen 300 is the edge closest to the handset. The geometric center of the projection 130 is defined as O, and the vertical distance between the geometric center O and the edge 310 is defined as D.

When the projection 130 has a fixed area, changing an aspect ratio of the projection 130 (that is, changing the L and W aspect ratio of the piezoelectric layer 13) changes the vibration frequency of the piezoelectric layer 13, and the sound volume of the loudspeaker 10 at different aspect ratios and different vibration frequencies are detected. In this embodiment, the closer that the projection 130 can be to a 1:1 aspect ratio, the better the sound generation effect of the loudspeaker 10.

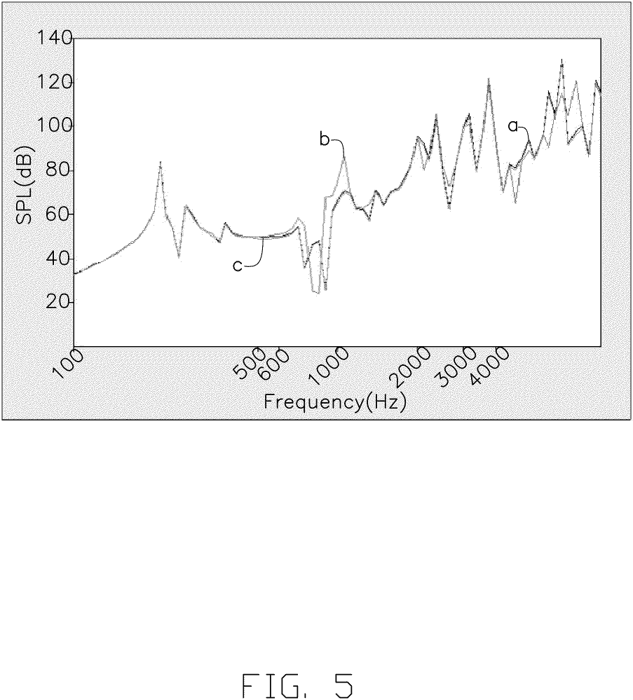

The horizontal axis of FIG. 5 represents the vibration frequency (frequency/Hz) of the piezoelectric layer 13, and the vertical axis represents the sound volume (SPL/DB) of the loudspeaker 10. FIG. 5 shows the variation curve of sound volume with vibration frequency at three values of distance D. In FIG. 5, curve a represents the variation curve of sound volume with vibration frequency when d = 5 mm, curve b represents the variation curve of sound volume with vibration frequency when d=50 mm, and curve c represents the variation curve of sound volume with vibration frequency when d=55 mm. As can be seen from FIG. 5, the greater the distance D, the better the sound generation effect of the loudspeaker 10. That is, the greater the distance between the loudspeaker 10 and the edge 310 closest to the handset on the screen 300, the better the sound generation effect of the loudspeaker 10.

The electronic device 100 of the present embodiment saves space in the electronic device 100 and miniaturizing and lightening the electronic device 100 by using a thin-film loudspeaker 10. By setting the size and position of the piezoelectric layer 13 in the loudspeaker 10, the sound generation effect of the loudspeaker 10 is improved (the volume is higher when driven by the same driving voltage).

### Second Embodiment

For convenience of description, the same elements in the second embodiment and the first embodiment adopt the same symbols. A main difference between the electronic device in this embodiment and the electronic device 100 in the first embodiment is the different shape of the piezoelectric layer 13 of the loudspeaker in the electronic device.

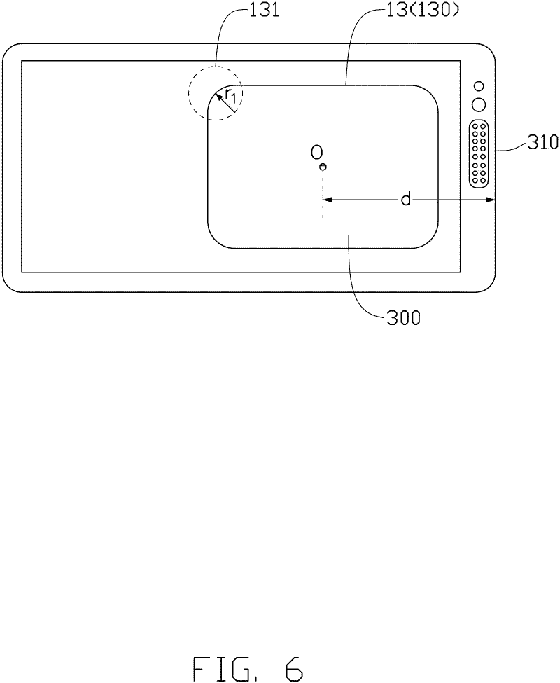

As shown in FIG. 6, in this embodiment, the piezoelectric layer 13 is a rectangle with a chamfer. That is, the projection 130 of the piezoelectric layer 13 on the screen 300 is shaped as a rectangle with chamfer. That is, the projection shape of the piezoelectric layer 13 on the screen 300 is rectangular, and each adjacent two edges are connected by an arc 131 rather than a right angle.

In this embodiment, the two adjacent edges being connected by an arc 131 rather than by a right angle allows the two adjacent edges to connect smoothly. When the piezoelectric layer 13 mechanically vibrates under the electric field, the two adjacent edges connect smoothly, so that the obstruction against vibration of the connection area of the two adjacent edges being at right angles is reduced by having the arc 131 instead.

Therefore, when the voltage differences on both sides of the piezoelectric layer 13 are the same, compared with the first embodiment in which the two adjacent edges are connected by the right angle, the present embodiment using the arc 131 connections increases the vibration frequency and the volume of the piezoelectric layer 13. That is, in this embodiment, the two adjacent edges of the piezoelectric layer 13 are connected by the arc 131.

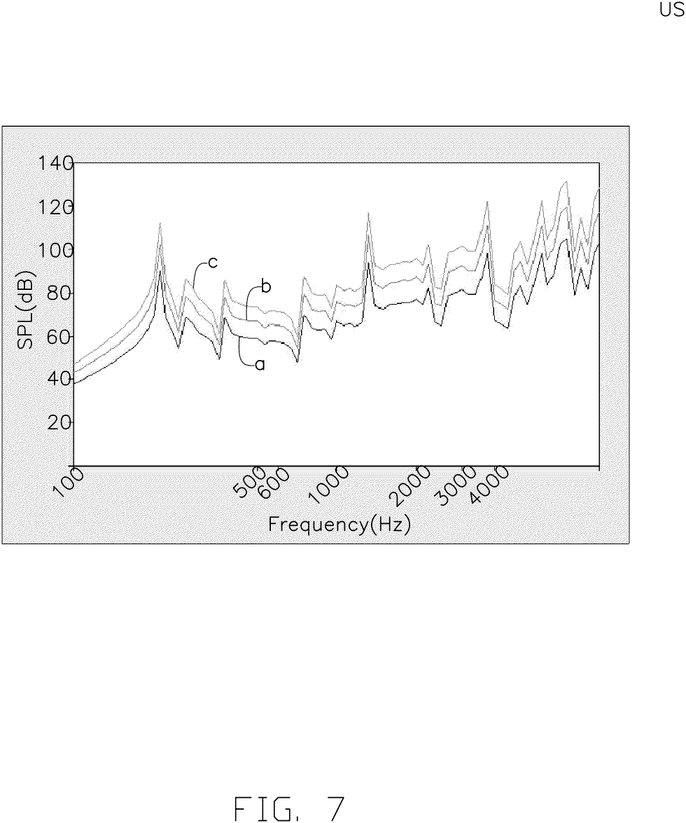

In this embodiment, a radius r1 of the arc 131 between each adjacent two edges is the same. In this embodiment, the radius r1 is 20 mm, and three variation curves of the sound volume with the vibration frequency are drawn when the distance D is taken as three values of D. In FIG. 7, curve a is a curve of sound volume varying with vibration frequency when d=45 mm, curve b is a curve of sound volume varying with vibration frequency when d=50 mm, and curve c is a curve of sound volume varying with vibration frequency when d=55 mm. A horizontal axis of FIG. 7 represents the vibration frequency (frequency/Hz) of the piezoelectric layer 13, and the vertical axis represents the sound volume (SPL/DB) of the loudspeaker 10. As can be seen from FIG. 7, the greater the distance D, the better the sound generation effect of the loudspeaker 10. That is, the greater the distance between the loudspeaker 10 and the edge 310 closest to the handset on the screen 300, the better is the sound generation effect of the loudspeaker 10.

The electronic device of the present embodiment realizes all the beneficial effects of the electronic device 100 in the first embodiment. In this embodiment, the two adjacent edges of the piezoelectric layer 13 are connected by the arc 131, which is conducive to further improving the sound generation effect of the loudspeaker.

### Third Embodiment

A main difference between the electronic device in this embodiment and the electronic device 100 in the first embodiment is in the different shape of the piezoelectric layer 13 of the loudspeaker in the electronic device.

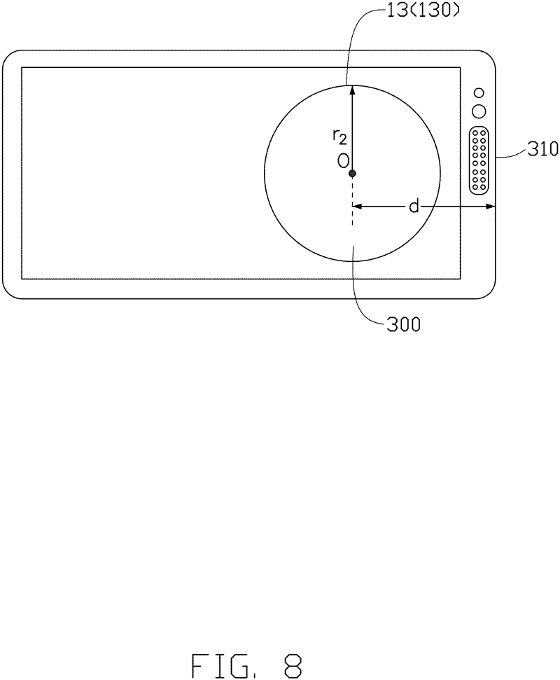

As shown in FIG. 8, in this embodiment, the piezoelectric layer 13 is circular. That is, a projection 130 of the piezoelectric layer 13 on the screen 300 is circular in shape. When the piezoelectric layer 13 is circular, the overall contour of the piezoelectric layer 13 is smoother than when the piezoelectric layer 13 is rectangular with chamfer. Therefore, compared with the second embodiment, the present embodiment further improves the sound generation effect of the loudspeaker.

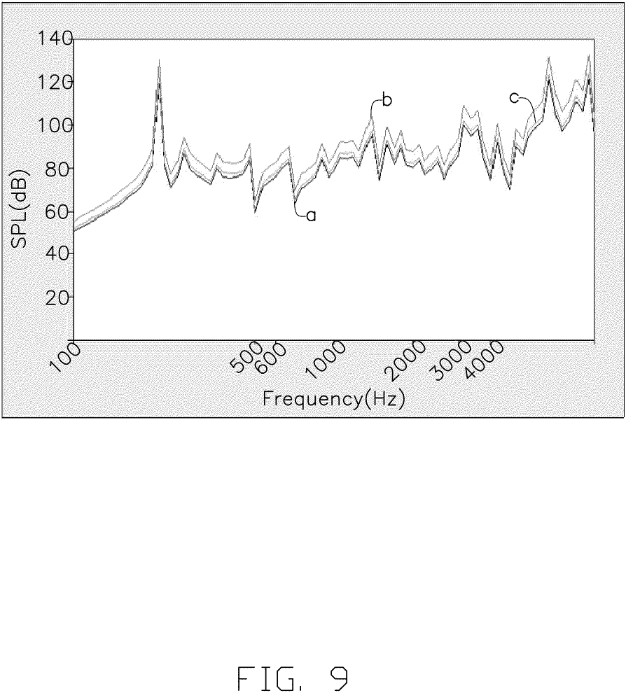

In this embodiment, a radius of the piezoelectric layer 13 is r2. The radius r2 is 28 mm, and three variation curves of the sound volume with the vibration frequency are drawn when the distance D is taken as three values of D. In FIG. 9, curve a is a curve of sound volume varying with vibration frequency when d=45 mm, curve b is a curve of sound volume varying with vibration frequency when d=50 mm, and curve c is a curve of sound volume varying with vibration frequency when d=55 mm. A horizontal axis of FIG. 9 represents the vibration frequency (frequency/Hz) of the piezoelectric layer 13, and the vertical axis represents the sound volume (SPL/DB) of the loudspeaker 10. As can be seen from FIG. 9, when the distance d=50 mm, the sound generation effect of loudspeaker 10 is better.

The electronic device of this embodiment can realize all the beneficial effects of the electronic device in the second embodiment. The present embodiment is conducive to further improving the sound generation effect of the speaker by setting the piezoelectric layer 13 as circular.

In other embodiments, the piezoelectric layer 13 may be a shape with a smooth outer contour rather than a circle and a rectangle with a chamfer. That is, the projection 130 of the piezoelectric layer 13 on the screen 300 may be other shapes having a smooth outer contour. In the present embodiment, the outer contour of the piezoelectric layer 13 is the outer contour of the projection pattern of the piezoelectric layer 13 on a plane parallel to the screen 300 (or parallel to the first or second electrode layers 11 and 12).

The “smooth outer contour” described in the present disclosure, that is, the outer contour of the piezoelectric layer 13, does not have sharp corners. In some embodiments, the projection of the outer contour of the piezoelectric layer 13 on the screen 300 is a closed curve, such as an ellipse, a circle in the third embodiment, or other irregular shape formed by the enclosure of the closed curve. In some embodiments, the projection of the outer profile of the piezoelectric layer 13 on the screen 300 includes at least one curved line segment and at least one straight line segment alternatively connected, such as the rectangle with chamfer described in the second embodiment (the rectangle with chamfer in the second embodiment can be regarded as being connected by the end of four curved segments and four straight segments in turn) or other irregular shape surrounded by curved line segments and straight line segments.

Due to sharp corners being a large obstruction against vibration, the piezoelectric layer 13 in the disclosure has a smooth outer contour, which is conducive to reducing the vibration obstruction of the low-voltage electric layer 13, so as to improve the sound generation effect of the loudspeaker 10 where the piezoelectric layer 13 is located.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A loudspeaker comprising:
a first electrode layer configured for receiving a first driving voltage;
a second electrode layer arranged opposite to the first electrode layer, the second electrode layer being configured for receiving a second driving voltage;
a piezoelectric layer between the first electrode layer and the second electrode layer;
wherein an outer contour of the piezoelectric layers is smooth, and a piezoelectric layer is configured for generating sound by mechanical vibrations according to the first driving voltage and the second driving voltage.

2. The loudspeaker of claim 1, wherein the outer contour of the piezoelectric layer is a closed curve.

3. The loudspeaker of claim 2, wherein the outer contour of the piezoelectric layer is circular.

4. The loudspeaker of claim 1, wherein an outer contour of the piezoelectric layer comprises at least one curved line segment and at least one straight line segment, and the at least one curved line segment and at least one straight line segment are alternatively connected.

5. The loudspeaker of claim 4, wherein an outer contour of the piezoelectric layer comprises four curved line segments and four straight line segments, and the four curved line segments and the four straight line segments are alternatively arranged.

6. The loudspeaker of claim 1, wherein the piezoelectric layer is made of a flexible piezoelectric material.

7. The loudspeaker of claim 1, wherein the piezoelectric layer is made of polyvinylidene fluoride.

8. An electronic device, comprising:
a housing;
a screen, the housing and the screen cooperating to form a receiving space; and
a loudspeaker located in the receiving space, the loudspeaker comprising:
a first electrode layer configured for receiving a first driving voltage;
a second electrode layer arranged opposite to the first electrode layer, the second electrode layer being configured for receiving a second driving voltage;
a piezoelectric layer between the first electrode layer and the second electrode layer;
wherein an outer contour of the piezoelectric layers is smooth, and a piezoelectric layer is configured for generating sound by mechanical vibrations according to the first driving voltage and the second driving voltage.

9. The electronic device of claim 8, wherein the outer contour of the piezoelectric layer is a closed curve.

10. The electronic device of claim 9, wherein the outer contour of the piezoelectric layer is circular.

11. The electronic device of claim 8, wherein an outer contour of the piezoelectric layer comprises at least one curved line segment and at least one straight line segment, and the at least one curved line segment and at least one straight line segment are alternatively connected.

12. The electronic device of claim 11, wherein an outer contour of the piezoelectric layer comprises four curved line segments and four straight line segments, and the four curved line segments and the four straight line segments are alternatively arranged.

13. The electronic device of claim 8, wherein the piezoelectric layer is made of a flexible piezoelectric material.

14. The electronic device of claim 8, wherein the piezoelectric layer is made of polyvinylidene fluoride.

15. The electronic device of claim 8, wherein the outer contour of the piezoelectric layer is an outer contour of a projection of the piezoelectric layer on the screen.

16. The electronic device of claim 8, wherein the electronic device is a mobile phone.
